(19) United States
(12) Patent Application Publication
(10) Pub. No.: US 2015/0313042 A1
(43) Pub. Date: Oct. 29, 2015

(54) OPTIMUM POWER INTERFACE BOARD POWER PERFORMANCE BY SERVER OR STORAGE SYSTEM

(71) Applicant: HON HAI PRECISION INDUSTRY CO., LTD., New Taipei (TW)

(72) Inventor: YU-CHI TSAI, New Taipei (TW)

(73) Assignee: HON HAI PRECISION INDUSTRY CO., LTD., New Taipei (TW)

(21) Appl. No.: 14/263,001

(22) Filed: Apr. 28, 2014

(51) Int. Cl. H05K 7/20; H05K 7/14; H05K 1/11

(52) U.S. Cl. CPC H05K 7/20709; H05K 1/117; H05K 7/1439; H05K 2201/10954

(57) ABSTRACT

A power interface board for a server includes a main board, a plurality of power interface connectors arranged on a front surface of the main board, and an output connector arranged on an end of the main board. The main board defines a plurality of cutouts through the surface of the main board. The power interface connectors are configured to electrically connect to power supply units of the server, and the output connector is configured to electrically connect to the power interface board of the server.

### FIELD

The present disclosure relates to power interface boards, and more specifically to power interface boards for a server or storage system.

### BACKGROUND

A power interface boards (PIB) provides connections from multiple power supply units (PSUs) to a power distribution board (PDB) or a planar motherboard (MB) to power components of the server or storage system. The PSUs are typically stacked on top of one another to save space in the server or storage system. The PIB has parallel functionality to supply power to the components. The PIB is typically designed in standard heights such as 2 U, 3 U, and 6 U. Proper airflow and ventilation is necessary to maintain the PSUs at their optimal thermal operating condition.

### BRIEF DESCRIPTION OF THE DRAWING

Many aspects of the present disclosure can be better understood with reference to the following drawings. The components in the drawings are not necessarily to scale, the emphasis instead being placed upon clearly illustrating the principles of the present embodiments.

FIG. 1 is an isometric view of an embodiment of a power interface board.

FIG. 2 is a side cross-sectional view of the power interface board of FIG. 1 shown connected to a pair of power supply units (illustrated diagrammatically) and a power distribution board.

### DETAILED DESCRIPTION

The disclosure is illustrated by way of example and not by way of limitation in the figures of the accompanying drawings in which like references indicate similar elements. It should be noted that references to “another,” “an,” or “one” embodiment in this disclosure are not necessarily to the same embodiment, and such references mean “at least one.”

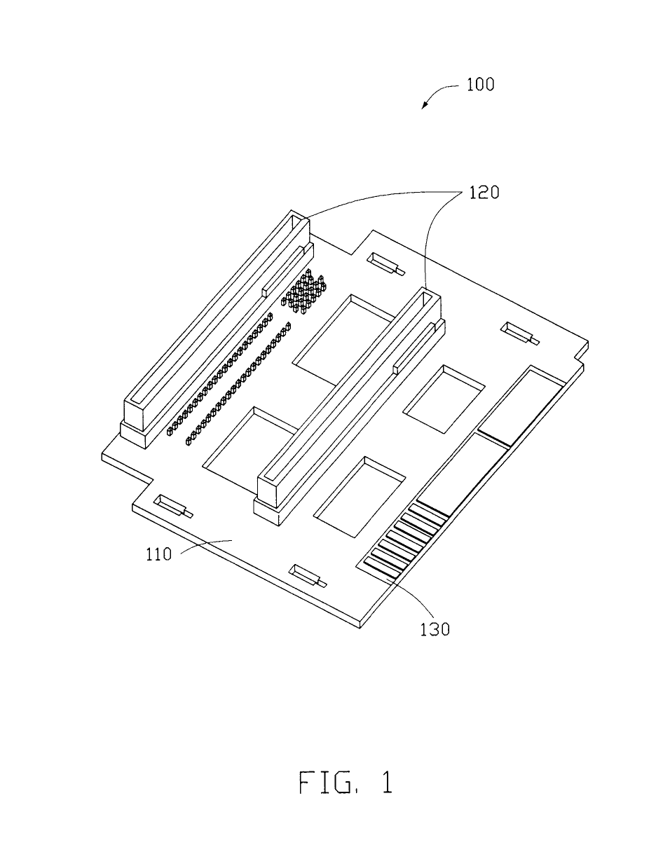

Referring to FIG. 1, an embodiment of a power interface board (PIB) 100 includes a main board 110, a plurality of power interface connectors 120 arranged on a front surface of the main board 110, and an output connector 130 arranged at an end of the main board 110.

The main board 110 can be planar. A plurality of cutouts 115 are defined through the front surface of the main board 110 adjacent to the power interface connectors 120.

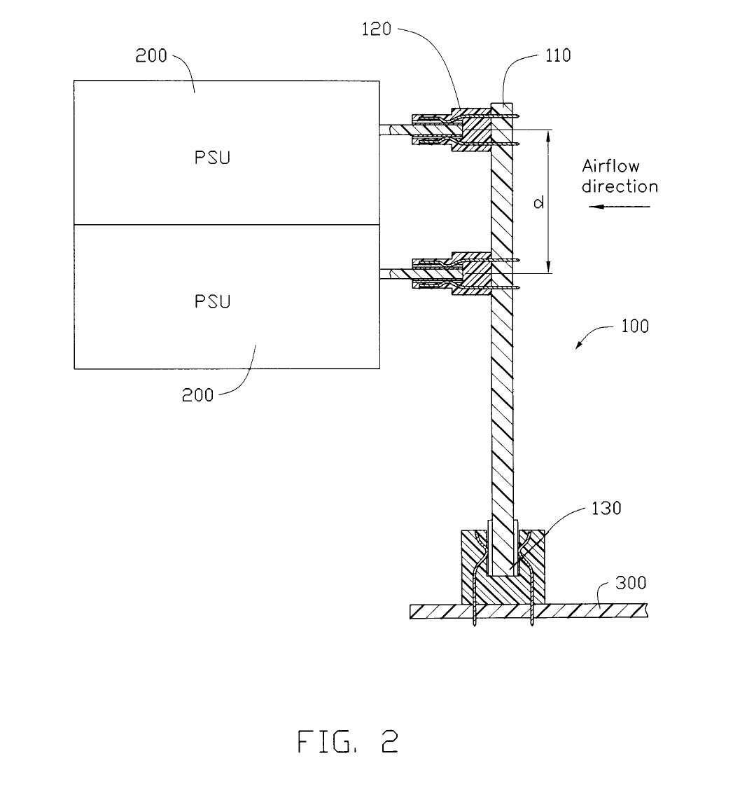

Referring also to FIG. 2, the power interface connecters 120 are substantially parallel to each other and substantially perpendicular to the main board 110. Each power interface connector 120 is configured to electrically connect directly or indirectly to a power supply unit (PSU) 200 of a server. The power interface connectors are separated by a distance d, such that one PSU 200 can be stacked directly above another PSU 200 with little or no gap between the two PSUs 200. The distance d can be approximately a thickness of one PSU 200. The cutouts 115 in the main board 110 are configured to allow air to flow through the main board 110 to provide cooling and ventilation for the PSUs 200. In one embodiment, the plurality of cutouts 115 are two pairs of cutouts with each pair of cutouts defined in the main board 110 adjacent to each power interface connector.

The output connector 130 can be substantially parallel or coplanar to the main board 110. The output connector 130 is configured to electrically connect directly or indirectly to a power distribution board (PDB) 300 or a motherboard (not shown) of the server. The output connector 130 can be a gold extension connector formed at the end of the main board 110. The output connector 130 can also be substantially perpendicular to the power interface connectors 120.

In assembly, each PSU 200 is electrically connected directly to a corresponding power interface connector 120, and one PSU 120 is stacked directly above another PSU 120. The output connector is electrically connected directly or indirectly to a PDB 300. The design of the PIB 100 does not require power cables, cable connectors, or ATX power connectors because the PIB 100 is directly mounted to the PDB 300. Furthermore, the output connector 130 is at an end of the main board 110. Therefore, there are no direct barriers to the path of air flowing through the cutouts 115 to the PSUs 200.

Finally, it is to be understood that the above-described embodiments are intended to illustrate rather than limit the present disclosure. Variations may be made to the embodiments without departing from the spirit of the present disclosure as claimed. Elements associated with any of the above embodiments are envisioned to be associated with any other embodiments. The above-described embodiments illustrate the scope of the present disclosure but do not restrict the scope of the present disclosure.

What is claimed is:

1. A power interface board (PIB) for a server, the server comprising a plurality of power supply units (PSUs) and a power distribution board (PDB), the PIB comprising:
a main board;
a plurality of power interface connectors arranged on a front surface of the main board; and
an output connector arranged at an end of the main board, wherein the main board defines a plurality of cutouts through the surface of the main board, the power interface connectors are configured to electrically connect to the PSUs, and the output connector is configured to electrically connect to the PDB.

2. The PIB of claim 1, wherein the plurality of cutouts are defined in the main board adjacent to the plurality of power interface connectors.

3. The PIB of claim 2, wherein the number of power interface connectors is two, and the plurality of cutouts are two pairs of cutouts with each pair of cutouts defined in the main board adjacent to each power interface connector.

4. The PIB of claim 1, wherein the power interface connectors are substantially parallel to each other.

5. The PIB of claim 4, wherein the power interface connectors are substantially perpendicular to the main board.

6. The PIB of claim 4, wherein the power interface connectors are separated by a distance which is substantially a thickness of one PSU.

7. The PIB of claim 1, wherein the output connector is substantially parallel to the main board.

8. The PIB of claim 7, wherein the output connector is a gold extension connector formed at the end of the main board.

9. The PIB of claim 7, wherein the output connector is substantially perpendicular to the power interface connectors.

10. The PIB of claim 1, wherein the main board is planar.

11. A power interface board (PIB) for a server, the server comprising a plurality of power supply units (PSUs) and a power distribution board (PDB), the PIB comprising:
a main board;
a plurality of power interface connectors arranged on a front surface of the main board; and
an output connector arranged at an end of the main board, wherein the main board defines a plurality of cutouts through the surface of the main board, the power interface connectors are configured to electrically connect to the PSUs, the output connector is configured to electrically connect to the PDB, and the output connector is substantially perpendicular to the power interface connectors.

12. The PIB of claim 11, wherein the plurality of cutouts are defined in the main board adjacent to the plurality of power interface connectors.

13. The PIB of claim 12, wherein the number of power interface connectors is two, and the plurality of cutouts are two pairs of cutouts with each pair of cutouts defined in the main board adjacent to each power interface connector.

14. The PIB of claim 11, wherein the power interface connectors are substantially parallel to each other.

15. The PIB of claim 14, wherein the power interface connectors are substantially perpendicular to the main board.

16. The PIB of claim 14, wherein the power interface connectors are separated by a distance which is substantially a thickness of one PSU.

17. The PIB of claim 11, wherein the output connector is a gold extension connector formed at the end of the main board.

18. The PIB of claim 11, wherein the main board is planar.
